(19) United States
(12) Patent Application Publication
(10) Pub. No.: US 2017/0110687 A1
(43) Pub. Date: Apr. 20, 2017

(54) FLEXIBLE DISPLAY DEVICE AND METHOD OF MANUFACTURING THE SAME

(71) Applicant: Samsung Display Co., Ltd., Yongin-si (KR)

(72) Inventors: Jeongho Kim, Yongin-si (KR); Kihyun Kim, Yongin-si (KR); Sunho Kim, Yongin-si (KR); Taewoong Kim, Yongin-si (KR); Yeongon Mo, Yongin-si (KR); Danbi Choi, Yongin-si (KR); Hayk Khachatryan, Yongin-si (KR)

(21) Appl. No.: 15/298,127

(22) Filed: Oct. 19, 2016

(30) Foreign Application Priority Data
Oct. 19, 2015 (KR) 10-2015-0145430

(51) Int. Cl. H01L 51/52; B32B 37/14; B32B 38/10; H01L 51/00; B32B 15/04

(52) U.S. Cl. CPC H01L 51/5253; H01L 51/0097; B32B 15/04; B32B 38/10; B32B 37/14; H01L 2251/5338; H01L 51/5237; H01L 2251/303; H01L 27/3244

(57) ABSTRACT

A flexible display device and method of manufacturing the same are disclosed. In one aspect, the flexible display device includes a flexible substrate including a first surface and a second surface opposite to the first surface and a display unit over the first surface of the flexible substrate. The flexible display device also includes a first barrier layer over the second surface of the flexible substrate and a first material layer between the first barrier layer and the flexible substrate, wherein the first material layer includes metal. The flexible display device can be more easily manufactured and resistant to external moisture permeation.

### CROSS-REFERENCE TO RELATED APPLICATION

This application claims the benefit of Korean Patent Application No. 10-2015-0145430, filed on Oct. 19, 2015, in the Korean Intellectual Property Office, the disclosure of which is incorporated herein in its entirety by reference.

### BACKGROUND

Field

One or more exemplary embodiments relate to a flexible display device and a method of manufacturing the same.

Description of the Related Technology

An organic light-emitting diode (OLED) display has drawn the attention as a next-generation display device due to its advantages such as a wide viewing angle, a high contrast ratio, and a speedy response rate.

Generally, when an OLED display is manufactured, thin film transistors and OLEDs are formed on a substrate, and the OLEDs emit light during operation. The organic light-emitting display device can be used as a display unit of a small product such as a cellular phone or a display unit of a large product such as a television (TV).

Recently, as there is a growing interest in flexible display devices, research on flexible display devices has been actively performed. A glass substrate is generally used to manufacture a flexible substrate. However, a flexible substrate formed of a material such as synthetic resin has been used recently to implement a flexible display device. Since the flexible substrate can easily bend, it is difficult to handle the flexible substrate in a manufacturing process. Accordingly, when the flexible display device is manufactured, a flexible substrate and various layers are formed on a support substrate having sufficient rigidity, and then, the flexible substrate is separated from the support substrate.

### SUMMARY OF CERTAIN INVENTIVE ASPECTS

One inventive aspect relates to a flexible display device resistant to external moisture permeation and having improved reliability and a method of manufacturing the flexible display device.

Another aspect is a flexible display device that includes: a flexible substrate including a first surface and a second surface opposite to the first surface; a display unit on the first surface of the flexible substrate; a first barrier layer on the second surface of the flexible substrate; and a first material layer between the first barrier layer and the flexible substrate and including metal.

The flexible display device may further include a second barrier layer between the flexible substrate and the display unit.

The first barrier layer and the second barrier layer may each include an inorganic material.

The first material layer may include metal oxide.

The flexible display device may further include a second material layer between the flexible substrate and the second barrier layer and including metal.

The second material layer may include metal oxide.

The flexible substrate may further include a side surface connecting the first surface and the second surface to each other, and the second barrier layer may cover the first surface and the side surface of the flexible substrate.

Another aspect is a flexible display device that includes: a flexible substrate including a first surface and a second surface opposite to the first surface; a display unit on the first surface of the flexible substrate; a first barrier layer on the second surface of the flexible substrate; and a first material layer between the flexible substrate and the display unit and including metal.

The flexible display device may further include a second barrier layer between the first material layer and the display unit.

The first material layer may include metal oxide.

Another aspect is a method of manufacturing a flexible display device that includes: forming a sacrificial layer on a support substrate, the sacrificial layer including an inorganic material; forming a first barrier layer on the sacrificial layer; forming a first material layer on the first barrier layer, the first material layer including metal; forming a flexible substrate on the first material layer; and separating the first barrier layer from the support substrate.

The method may further include forming a display unit on the flexible substrate, and forming a second barrier layer between the flexible substrate and the display unit.

The first barrier layer and the second barrier layer may each include an inorganic material.

The method may further include forming a second material layer between the flexible substrate and the second barrier layer, the second material layer including metal.

The second material layer may further include oxygen binding to the metal.

The sacrificial layer may include an oxide including at least one refractory metal.

The first material layer may further include oxygen binding to the metal.

These general and specific embodiments may be implemented by using a system, a method, a computer program, or a combination thereof.

Another aspect is a flexible display device comprising: a flexible substrate comprising a first surface and a second surface opposite to the first surface; a display unit over the first surface of the flexible substrate; a first barrier layer over the second surface of the flexible substrate; and a first material layer between the first barrier layer and the flexible substrate, wherein the first material layer comprises metal.

The above display device further comprises a second barrier layer between the flexible substrate and the display unit. In the above display device, each of the first and second barrier layers comprises an inorganic material. In the above display device, the first material layer comprises metal oxide. The above display device further comprises a second material layer between the flexible substrate and the second barrier layer, wherein the second material layer comprises metal. In the above display device, the second material layer comprises metal oxide.

In the above display device, the flexible substrate further comprises a side surface interconnecting the first and second surfaces, and wherein the second barrier layer covers the first surface and the side surface of the flexible substrate. In the above display device, the side surface of the flexible substrate directly contacts the first material layer. In the above display device, the first material layer has the same width as that of the first barrier layer and that of the flexible substrate. In the above display device, the first material layer is thinner than the flexible substrate.

Another aspect is a flexible display device comprising: a flexible substrate comprising a first surface and a second surface opposite to the first surface; a display unit over the first surface of the flexible substrate; a first barrier layer over the second surface of the flexible substrate; and a first material layer between the flexible substrate and the display unit, wherein the first material layer comprises metal.

The above display device further comprises a second barrier layer between the first material layer and the display unit. In the above display device, the first material layer comprises metal oxide.

Another aspect is a method of manufacturing a flexible display device, the method comprising: forming a sacrificial layer over a support substrate, the sacrificial layer comprising an inorganic material; forming a first barrier layer over the sacrificial layer; forming a first material layer over the first barrier layer, the first material layer comprising metal; forming a flexible substrate over the first material layer; and separating the first barrier layer from the support substrate.

The above method further comprises: forming a display unit over the flexible substrate; and forming a second barrier layer between the flexible substrate and the display unit.

In the above method, each of the first and second barrier layers comprises an inorganic material. The above method further comprises forming a second material layer between the flexible substrate and the second barrier layer, the second material layer comprising metal. In the above method, the second material layer further comprises oxygen binding to the metal. In the above method, the sacrificial layer comprises an oxide comprising at least one refractory metal. In the above method, the first material layer further comprises oxygen binding to the metal.

### BRIEF DESCRIPTION OF THE DRAWINGS

These and/or other aspects will become apparent and more readily appreciated from the following description of the exemplary embodiments, taken in conjunction with the accompanying drawings.

FIG. 1 is a schematic cross-sectional view of a stacked structure of a flexible display device according to an exemplary embodiment.

FIG. 2 is a schematic cross-sectional view of a stacked structure of a flexible display device according to another exemplary embodiment.

FIG. 3 is a schematic cross-sectional view of a stacked structure of a flexible display device according to another exemplary embodiment.

FIG. 4 is a schematic cross-sectional view of a stacked structure of a flexible display device according to another exemplary embodiment.

FIG. 5 is a schematic cross-sectional view of a structure of a display unit of a flexible display device according to an exemplary embodiment.

FIGS. 6 to 9 are schematic cross-sectional views of a process of manufacturing a flexible display device according to an exemplary embodiment.

### DETAILED DESCRIPTION OF CERTAIN INVENTIVE EMBODIMENTS

Generally, when a flexible substrate includes two or more layers in order to prevent moisture permeation from the flexible substrate, a manufacturing process may become complicated. Furthermore, when a flexible substrate includes a single layer, the flexible substrate and a support substrate may not be detached from each other or external air may penetrate through the bottom of the flexible substrate, and accordingly, the flexible display device may have decreased reliability.

As the inventive concept allows for various changes and numerous embodiments, exemplary embodiments will be illustrated in the drawings and described in detail in the written description. Advantages and features of one or more exemplary embodiments and methods of accomplishing the same may be understood more readily by reference to the following detailed description of the one or more exemplary embodiments and the accompanying drawings. The inventive concept may, however, be embodied in many different forms and should not be construed as being limited to the one or more exemplary embodiments set forth herein.

Reference will now be made in detail to exemplary embodiments, examples of which are illustrated in the accompanying drawings. Like reference numerals in the drawings denote like elements, and a repeated description thereof will be omitted. The term “and/or” used herein includes any and all combinations of one or more of the associated listed items.

While such terms as “first” and “second” may be used to describe various components, such components must not be limited to the above terms. The above terms are used only to distinguish one component from another. The singular forms “a,” “an,” and “the” used herein are intended to include the plural forms as well, unless the context clearly indicates otherwise.

It will be understood that the terms such as “include,” “comprise,” and “have” used herein specify the presence of stated features or components, but do not preclude the presence or addition of one or more other features or components. It will be further understood that when a layer, region, or component is referred to as being “on” another layer, region, or component, it can be directly or indirectly on the other layer, region, or component. That is, for example, intervening layers, regions, or components may be present.

Sizes of components in the drawings may be exaggerated for convenience of explanation. In other words, since sizes and thicknesses of components in the drawings are arbitrarily illustrated for convenience of explanation, exemplary embodiments are not limited thereto.

The x-axis, the y-axis and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

When an embodiment may be implemented differently, a specific process order may be performed differently from the described order. For example, two consecutively described processes may be performed substantially at the same time or performed in an order opposite to the described order.

In this disclosure, the term “substantially” includes the meanings of completely, almost completely or to any significant degree under some applications and in accordance with those skilled in the art. Moreover, “formed, disposed over positioned over” can also mean “formed, disposed or positioned on.” The term “connected” includes an electrical connection.

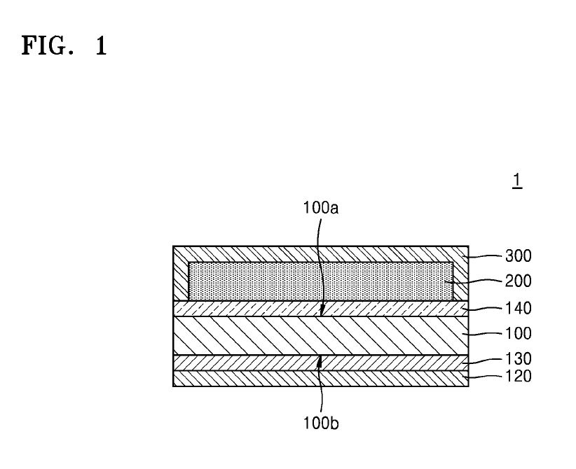

FIG. 1 is a schematic cross-sectional view of a stacked structure of a flexible display device 1 according to an exemplary embodiment.

Referring to FIG. 1, the flexible display device 1 includes a flexible substrate 100, a display unit 200 for displaying an image, a first barrier layer 120, a second barrier layer 140, and a first material layer 130 including metal.

The flexible substrate 100 may be bent and may include plastic with excellent heat-resisting properties and durability. For example, the flexible substrate 100 may include one selected from the group consisting of polyethersulfone (PES), polyacrylate (PA), polyetherimide (PEI), polyethylene naphthalate (PEN), polyethylene terephthalate (PET), polyphenylene sulfide (PPS), polyarylate (PAR), polyimide (PI), polycarbonate (PC), cellulose triacetate, cellulose acetate propionate (CAP), poly(arylene ether sulfone), and a combination thereof.

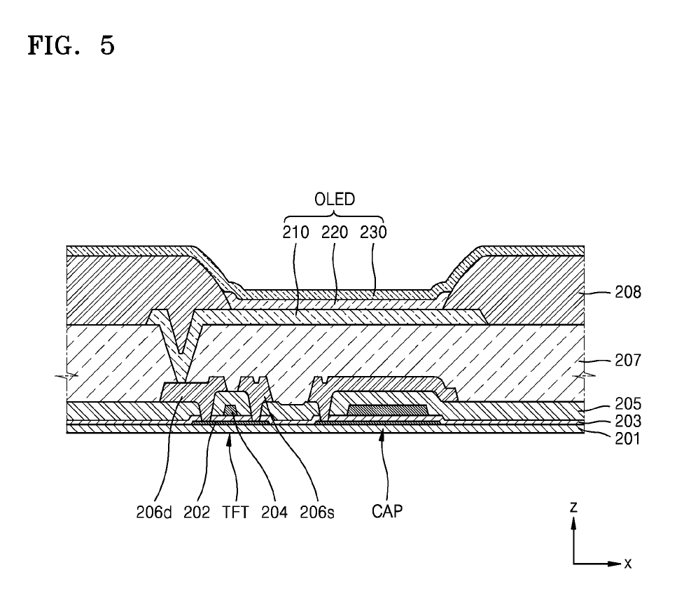

The flexible substrate 100 may have a first surface 100a and a second surface 100b opposite to the first surface 100a. The display unit 200 may be disposed on the first surface 100a of the flexible substrate 100. The display unit 200 may include a thin film transistor TFT (refer to FIG. 5) and a light-emitting device electrically connected to the thin film transistor TFT. The display unit 200 may be a liquid crystal display unit or an organic light-emitting display unit.

A thin film encapsulation layer 300 may be disposed on the display unit 200 and seal the display unit 200 from the outside. Although not illustrated in FIG. 1, the thin film encapsulation layer 300 may have a structure in which an organic film and an inorganic film, which each include one or more layers, are alternately stacked. Since the thin film encapsulation layer 300 has to prevent external air flowing into the display unit 200 from the outside, an end of the thin film encapsulation layer 300 may contact the flexible substrate 100 or the second barrier layer 140, which will be described later, so as to completely cover the display unit 200.

The first barrier layer 120 may be disposed on the second surface 100b of the flexible substrate 100. The first barrier layer 120 may include an inorganic material and for example, may include silicon oxide and/or silicon nitride, but exemplary embodiments are not limited thereto.

The second barrier layer 140 may be disposed on the first surface 100a of the flexible substrate 100 and may be between the flexible substrate 100 and the display unit 200. The second barrier layer 140 may include an inorganic material and for example, may include silicon oxide and/or silicon nitride, but the described technology is not limited thereto. The second barrier layer 140 may serve as a protective layer which prevents impurities having flowed into the flexible substrate 100 from reaching the display unit 200.

The flexible display device 1 includes the first material layer 130 between the flexible substrate 100 and the first barrier layer 120. The first material layer 130 may include metal and/or metal oxide. For example, the first material layer 130 may include at least one material selected from indium tin oxide (ITO), aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu) and/or oxide of the at least one material, but exemplary embodiments are not limited thereto.

As described above, the first material layer 130 may be between the flexible substrate 100 and the first barrier layer 120. The first material layer 130 may be directly between the flexible substrate 100 and the first barrier layer 120 and may directly contact the flexible substrate 100 and the first barrier layer 120 surface-to-surface. The first material layer 130 may be thinner than the flexible substrate 100. Furthermore, the thickness of the first material layer 130 may be similar to or the same as that of the first barrier layer 120. The first material layer 130 may have substantially the same width as that of the flexible substrate 100 and/or the first barrier layer 120. The first barrier layer 120 is disposed on the second surface 100b of the flexible substrate 100 in order to prevent external air permeation from the second surface 100b of the flexible substrate 100. The first barrier layer 120 may include an inorganic material, whereas the flexible substrate 100 may include an organic material such as plastic. Accordingly, although the flexible substrate 100 and the first barrier layer 120 are closely attached to each other in order to prevent external air permeation into the flexible substrate 100, a problem such as poor detachment or bubble formation between an organic layer and an inorganic layer may occur due to a difference in properties of the materials of the flexible substrate 100 and the first barrier layer 120.

In the flexible display device 1 according to an exemplary embodiment, the above-described problem may be solved by disposing the first material layer 130, which includes metal or metal oxide, between the flexible substrate 100 and the first barrier layer 120. One surface of the first material layer 130 contacts the flexible substrate 100 and at the same time, the second surface of the first material layer 130 contacts the first barrier layer 120, the first material layer 130 including metal or metal oxide. The first material layer 130 including metal or metal oxide has excellent adhesion characteristics with both an organic layer and an inorganic layer and accordingly, the first material layer 130 between the flexible substrate 100 and the first barrier layer 120 may significantly solve issues of poor detachment, bubble formation between an organic layer and an inorganic layer, or the like, which are due to a difference in properties of materials of the layers. Also, as the first material layer 130 may serve as a barrier as well, an effect that two or more flexible substrates 100 are provided may be produced.

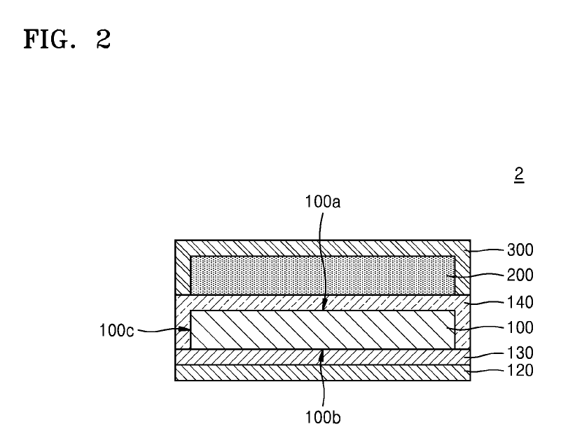

FIG. 2 is a schematic cross-sectional view of a stacked structure of a flexible display device 2 according to another exemplary embodiment.

Since the flexible display device 2 of FIG. 2 is the same as the flexible display device 1 of FIG. 1 except the structure of the second barrier layer 140, a repeated description thereof is omitted.

Referring to FIG. 2, the second barrier layer 140 may be between the flexible substrate 100 and the display unit 200. In the present exemplary embodiment, the second barrier layer 140 may cover both the first surface 100a and a side surface 100c of the flexible substrate 100. Accordingly, an end of the second barrier layer 140 may contact the first material layer 130. Due to such a structure, the second barrier layer 140 may block impurities which may flow into the bottom surface of the display unit 200 and at the same time, may block impurities which may flow into the side surface 100c of the flexible substrate 100.

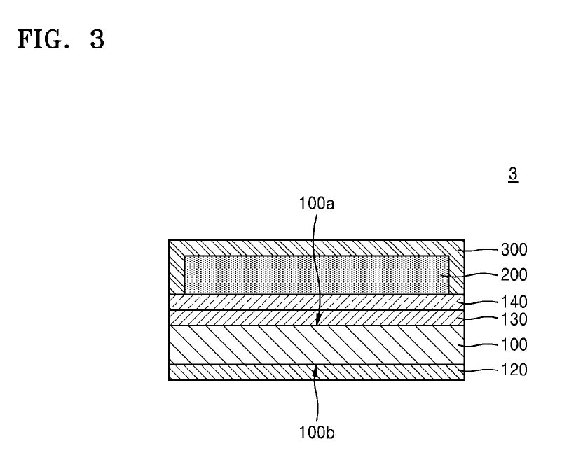

FIG. 3 is a schematic cross-sectional view of a stacked structure of a flexible display device 3 according to another exemplary embodiment.

Referring to FIG. 3, the flexible display device 3 includes the flexible substrate 100, the display unit 200 for displaying an image, the first barrier layer 120, the second barrier layer 140, and the first material layer 130 including metal.

The flexible substrate 100, which has flexible characteristics, may include one or more materials, such as PET, PEN, and plastic such as polyimide.

The flexible substrate 100 may have the first surface 100a and the second surface 100b opposite to the first surface 100a. The display unit 200 may be disposed on the first surface 100a of the flexible substrate 100. The display unit 200 may include a thin film transistor and a light-emitting device electrically connected to the thin film transistor. The display unit 200 may be a liquid crystal display unit or an organic light-emitting display unit.

The thin film encapsulation layer 300 may be disposed on the display unit 200 and seal the display unit 200 from the environment. Although not illustrated in FIG. 3, the thin film encapsulation layer 300 may have a structure in which an organic film and an inorganic film, which each include one or more layers, are alternately stacked. Since the thin film encapsulation layer 300 has to prevent external air flowing into the display unit 200 from the environment, an end of the thin film encapsulation layer 300 may contact the flexible substrate 100 or the second barrier layer 140, which will be described below, so as to completely cover the display unit 200.

The first barrier layer 120 may be disposed on the second surface 100b of the flexible substrate 100. The first barrier layer 120 may include an inorganic material and for example, may include silicon oxide and/or silicon nitride, but the described technology is not limited thereto.

The second barrier layer 140 may be disposed on the first surface 100a of the flexible substrate 100 and may be between the flexible substrate 100 and the display unit 200. The second barrier layer 140 may include an inorganic material and for example, may include silicon oxide and/or silicon nitride, but the described technology is not limited thereto. The second barrier layer 140 may serve as a protective layer which prevents impurities having flowed into the flexible substrate 100 from reaching the display unit 200.

The flexible display device 3 includes the first material layer 130 between the flexible substrate 100 and the second barrier layer 140. The first material layer 130 may include metal and/or metal oxide. For example, the first material layer 130 may include at least one material selected from indium tin oxide (ITO), aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu) and/or oxide of the at least one material, but exemplary embodiments are not limited thereto.

As described above, the first material layer 130 may be between the flexible substrate 100 and the second barrier layer 140. The first material layer 130 may be directly between the flexible substrate 100 and the second barrier layer 140 and may directly contact the flexible substrate 100 and the second barrier layer 140 surface-to-surface.

The second barrier layer 140 is disposed on the first surface 100a of the flexible substrate 100 in order to prevent external air permeation from the first surface 100a of the flexible substrate 100. The second barrier layer 140 may include an inorganic material, whereas the flexible substrate 100 may include an organic material such as plastic. Accordingly, although the flexible substrate 100 and the second barrier layer 140 are closely attached to each other in order to prevent external air permeation into the flexible substrate 100, a problem of poor detachment or bubble formation between an organic layer and an inorganic layer may occur due to a difference in properties of the materials of the flexible substrate 100 and the second barrier layer 140.

In the flexible display device 3 according to an exemplary embodiment, the above-described problem may be solved by disposing the first material layer 130, which includes metal or metal oxide, between the flexible substrate 100 and the second barrier layer 140. One surface of the first material layer 130 contacts the flexible substrate 100 and at the same time, the other surface of the first material layer 130 contacts the second barrier layer 140, the first material layer 130 including metal or metal oxide. The first material layer 130 including metal or metal oxide has excellent adhesion characteristics with both an organic layer and an inorganic layer and accordingly, the first material layer 130 between the flexible substrate 100 and the second barrier layer 140 may significantly solve issues of poor detachment, bubble formation between an organic layer and an inorganic layer, or the like, which are due to a difference in properties of materials of the layers.

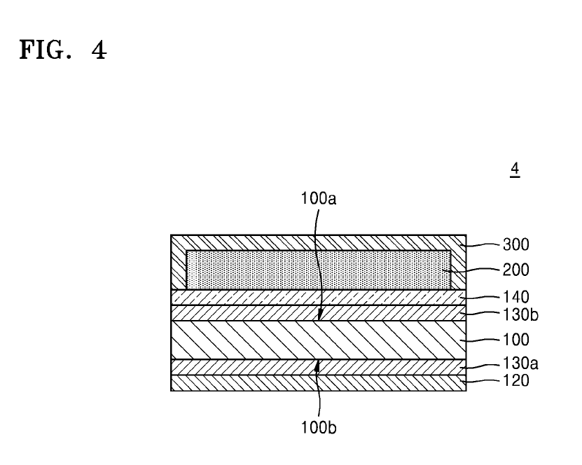

FIG. 4 is a schematic cross-sectional view of a stacked structure of a flexible display device 4 according to another exemplary embodiment.

Referring to FIG. 4, the flexible display device 4 includes the flexible substrate 100, the display unit 200 for displaying an image, the first barrier layer 120, the second barrier layer 140, a first material layer 130a including metal, and a second material layer 130b.

The flexible substrate 100, which has flexible characteristics, may include one or more materials, such as PET, PEN, and plastic such as polyimide.

The flexible substrate 100 may have the first surface 100a and the second surface 100b opposite to the first surface 100a. The display unit 200 may be disposed on the first surface 100a of the flexible substrate 100. The display unit 200 may include a thin film transistor and a light-emitting device electrically connected to the thin film transistor. The display unit 200 may be a liquid crystal display unit or an organic light-emitting display unit.

The thin film encapsulation layer 300 may be disposed on the display unit 200 and seal the display unit 200 from the outside. Although not illustrated in FIG. 4, the thin film encapsulation layer 300 may have a structure in which an organic film and an inorganic film, which each include one or more layers, are alternately stacked. Since the thin film encapsulation layer 300 has to prevent external air flowing into the display unit 200 from the outside, an end of the thin film encapsulation layer 300 may contact the flexible substrate 100 or the second barrier layer 140, which will be described below, so as to completely cover the display unit 200.

The first barrier layer 120 may be disposed on the second surface 100b of the flexible substrate 100. The first barrier layer 120 may include an inorganic material and for example, may include silicon oxide and/or silicon nitride, but exemplary embodiments are not limited thereto.

The second barrier layer 140 may be disposed on the first surface 100a of the flexible substrate 100 and may be between the flexible substrate 100 and the display unit 200. The second barrier layer 140 may include an inorganic material and for example, may include silicon oxide and/or silicon nitride, but exemplary embodiments are not limited thereto. The second barrier layer 140 may serve as a protective layer which prevents impurities having flowed into the flexible substrate 100 from reaching the display unit 200.

The flexible display device 4 according to the present exemplary embodiment may include the first material layer 130a between the flexible substrate 100 and the first barrier layer 120. The first material layer 130a may include metal and/or metal oxide.

As described above, the first material layer 130a may be between the flexible substrate 100 and the first barrier layer 120. The first material layer 130a may be directly between the flexible substrate 100 and the first barrier layer 120 and may directly contact the flexible substrate 100 and the first barrier layer 120 surface-to-surface.

Also, the flexible display device 4 according to the present exemplary embodiment may include the second material layer 130b between the flexible substrate 100 and the second barrier layer 140.

As described above, the second material layer 130b may be between the flexible substrate 100 and the second barrier layer 140. The second material layer 130b may be directly between the flexible substrate 100 and the second barrier layer 140 and may directly contact the flexible substrate 100 and the second barrier layer 140 surface-to-surface.

The first material layer 130a and the second material layer 130b may each include metal and/or metal oxide. For example, the first material layer 130a and the second material layer 130b may each include at least one material selected from indium tin oxide (ITO), aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu) and/or oxide of the at least one material, but exemplary embodiments are not limited thereto.

The second barrier layer 140 disposed on the first surface 100a of the flexible substrate 100 and the first barrier layer 120 disposed on the second surface 100b are respectively disposed on the first surface 100a and the second surface 100b of the flexible substrate 100 in order to prevent external air permeation from the flexible substrate 100. The first barrier layer 120 and the second barrier layer 140 may each include an inorganic material, whereas the flexible substrate 100 may include an organic material such as plastic. Accordingly, although the flexible substrate 100 and the first and second barrier layers 120 and 140 have to be closely attached to each other in order to prevent external air permeation into the flexible substrate 100, a problem such as an issue of poor detachment or an issue of bubble formation between an organic layer and an inorganic layer may occur due to a difference in properties of the materials of the flexible substrate 100 and the first and second barrier layers 120 and 140.

In the flexible display device 4 according to an exemplary embodiment, the above-described problem may be solved by disposing the first material layer 130a and the second material layer 130b, each of which includes metal and/or metal oxide, respectively between the flexible substrate 100 and the first barrier layer 120 and between the flexible substrate 100 and the second barrier layer 140. The thickness of the first material layer 130a may be similar to or the same as that of the second material layer 130b. One surface of the first material layer 130a contacts the flexible substrate 100 and at the same time, the other surface of the first material layer 130a contacts the first barrier layer 120, the first material layer 130a including metal or metal oxide. In the same manner, one surface of the second material layer 130b contacts the flexible substrate 100, and at the same time, the other surface of the second material layer 130b contacts the second barrier layer 140, the second material layer 130b including metal or metal oxide. The first material layer 130a and the second material layer 130b each including metal and/or metal oxide have excellent adhesion characteristics with both an organic layer and an inorganic layer and accordingly, the first material layer 130a and the second material layer 130b respectively between the flexible substrate 100 and the first barrier layer 120 and between the flexible substrate 100 and the second barrier layer 140, may significantly solve issues of poor detachment, bubble formation between an organic layer and an inorganic layer, or the like, which are due to a difference in properties of materials of the layers.

FIG. 5 is a schematic cross-sectional view of a structure of the display unit 200 of the flexible display device 1, 2, 3, or 4 according to an exemplary embodiment.

Referring to FIGS. 1 to 5, the display unit 200 may be disposed on the flexible substrate 100, and the display unit 200 may include an OLED, the thin film transistor TFT electrically connected to the OLED, and a capacitor CAP. As described above, the display unit 200 may be a liquid crystal display unit or an organic light-emitting display unit. However, in the present exemplary embodiment, a case in which the display unit 200 is an organic light-emitting display unit will be described as an example.

A buffer layer 201 including silicon oxide, silicon nitride, or the like may be disposed on the flexible substrate 100 to planarize a surface of the flexible substrate 100 or prevent impurities, etc. from penetrating into a semiconductor layer 202 of the thin film transistor TFT, and the semiconductor layer 202 may be disposed on the buffer layer 201.

In the present exemplary embodiment, as illustrated in FIG. 1, the second barrier layer 140 may be between the flexible substrate 100 and the buffer layer 201.

A gate electrode 204 is disposed on the semiconductor layer 202, and a source electrode 206s and a drain electrode 206d are electrically connected to each other according to a signal applied to the gate electrode 204. The gate electrode 204 may include a single layer or layers including, for example, at least one material selected from aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu) by taking into account factors such as adhesiveness to an adjacent layer, surface smoothness of a stacked layer, and processability.

In this regard, in order to secure insulation between the semiconductor layer 202 and the gate electrode 204, a gate insulation layer 203 including silicon oxide and/or silicon nitride may be between the semiconductor layer 202 and the gate electrode 204.

An interlayer insulation layer 205 may be disposed on the gate electrode 204 and may include a single layer or layers including a material such as silicon oxide or silicon nitride.

The source electrode 206s and the drain electrode 206d are disposed on the interlayer insulation layer 205. Each of the source electrode 206s and the drain electrode 206d is electrically connected to the semiconductor layer 202 via a contact hole formed in the interlayer insulation layer 205 and the gate insulation layer 203. The source electrode 206s and the drain electrode 206d may each include a single layer or layers including, for example, at least one material selected from aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu) by taking into account a factor such as conductivity.

Although not illustrated, a protective layer (not shown) covering the thin film transistor TFT may be provided to protect the thin film transistor TFT having such a structure. The protective layer may include an inorganic material such as silicon oxide, silicon nitride, or silicon oxynitride.

A first insulation layer 207 may be disposed on the thin film transistor TFT. In this case, the first insulation layer 207 may be a planarization layer or a protective layer. When an organic light-emitting device is disposed on the thin film transistor TFT, the first insulation layer 207 substantially planarizes the top surface of the thin film transistor TFT and protects the thin film transistor TFT and various devices. The first insulation layer 207 may include, for example, an acrylic organic material, benzocyclobutene (BCB), or the like. In this regard, as illustrated in FIG. 5, the buffer layer 201, the gate insulation layer 203, the interlayer insulation layer 205, and the first insulation layer 207 may be formed on the entire surface of the flexible substrate 100.

A second insulation layer 208 may be disposed on the thin film transistor TFT. In this case, the second insulation layer 208 may be a pixel-defining layer. The second insulation layer 208 may be disposed on the above-described first insulation layer 207 and may have an opening. The second insulation layer 208 may define a pixel region on the flexible substrate 100.

The second insulation layer 208 may include, for example, an organic insulation layer. The organic insulation layer may include an acrylic polymer such as poly(methyl methacrylate) (PMMA), polystyrene (PS), a polymer derivative containing a phenol group, an imide-based polymer, an aryl ether-based polymer, an amide-based polymer, a fluorine-based polymer, a p-xylene-based polymer, a vinyl alcohol-based polymer, and a mixture thereof.

The OLED may be disposed on the second insulation layer 208. The OLED may include a pixel electrode 210, an intermediate layer 220 including an emission layer (EML), and an opposite electrode 230.

The pixel electrode 210 may be a (semi)transparent electrode or a reflective electrode. When the pixel electrode 210 is a (semi)transparent electrode, the pixel electrode 210 may include, for example, indium tin oxide (ITO), indium zinc oxide (IZO), zinc oxide (ZnO), indium oxide (In₂O₃), indium gallium oxide (IGO), or aluminum zinc oxide (AZO). When the pixel electrode 210 is a reflective electrode, the pixel electrode 210 may include a reflective layer including Ag, Mg, Al, Pt, Pd, Au, Ni, Nd, Ir, Cr, and a compound thereof, and a layer including ITO, IZO, ZnO, In₂O₃, IGO, or AZO. However, exemplary embodiments are not limited thereto. The pixel electrode 210 may include various materials, and a structure of the pixel electrode 210 may be modified in various ways such as including a single layer or layers.

An intermediate layer 220 may be disposed in each pixel region defined by the second insulation layer 208. The intermediate layer 220 includes an EML that emits light according to an electrical signal. In addition to the EML, the intermediate layer 220 may include a hole injection layer (HIL) and a hole transport layer (HTL) between the EML and the pixel electrode 210, an electron transport layer (ETL) and an electron injection layer (EIL) between the EML and the opposite electrode 230, and the like stacked on one another in a single or complex structure. However, the intermediate layer 220 is not limited thereto and may have various structures.

The opposite electrode 230 covering the intermediate layer 220 including an EML and facing the pixel electrode 210 may be disposed over the entire surface of the flexible substrate 100. The opposite electrode 230 may be a (semi)transparent electrode or a reflective electrode.

When the opposite electrode 230 is a (semi)transparent electrode, the opposite electrode 230 may include a layer including metal with a low work function, that is, Li, Ca, lithium fluoride/calcium (LiF/Ca), lithium fluoride/aluminum (LiF/Al), Al, Ag, Mg, and a compound thereof, and a (semi)transparent conductive layer including ITO, IZO, ZnO, In₂O₃, or the like. When the opposite electrode 230 is a reflective electrode, the opposite electrode 230 may include a layer including Li, Ca, LiF/Ca, LiF/Al, Al, Ag, Mg, and a compound thereof. However, a structure and a material of the opposite electrode 230 are not limited thereto and may have various modifications.

Although a flexible display device has been mainly described above, exemplary embodiments are not limited thereto. For example, a flexible display device manufacturing method for manufacturing such a flexible display device may also be within the scope of the inventive concept.

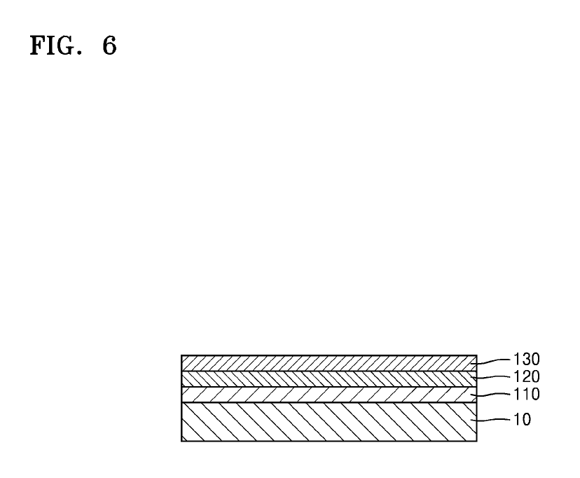

FIGS. 6 to 9 are schematic cross-sectional views of a process of manufacturing the flexible display device 1 according to an exemplary embodiment.

Referring to FIG. 6, a sacrificial layer 110 including an inorganic material may be formed on a support substrate 10, the first barrier layer 120 may be formed on the sacrificial layer 110, and then, the first material layer 130 including metal and/or metal oxide may be formed on the first barrier layer 120.

The support substrate 10 may include glass, metal, or the like and may support various layers formed on a flexible substrate during the manufacturing process.

The sacrificial layer 110 may include oxide including at least one refractory metal. Refractory metals, which are metals that do not melt even under strong heat and highly resistant to strong heat or alloys of those metals, generally refer to metals that do not melt even in a high temperature of 1100° C. or greater. The refractory metals may include, for example, niobium (Nb), molybdenum (Mo), tantalum (Ta), tungsten (W), and titanium (Ti). As the sacrificial layer 110 including oxide of such a refractory metal is formed on the entire surface of the support substrate 10, an issue where a flexible substrate is damaged or fails to be detached from a support substrate during a process of separating the flexible substrate from the support substrate may be solved.

The first barrier layer 120 may be formed on the sacrificial layer 110. The first barrier layer 120 may include an inorganic material and for example, may include silicon oxide and/or silicon nitride. However, exemplary embodiments are not limited thereto.

The first material layer 130 may be formed on the first barrier layer 120. The first material layer 130 may include metal and/or metal oxide. For example, the first material layer 130 may include at least one material selected from indium tin oxide (ITO), aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu) and/or oxide of the at least one material, but exemplary embodiments are not limited thereto.

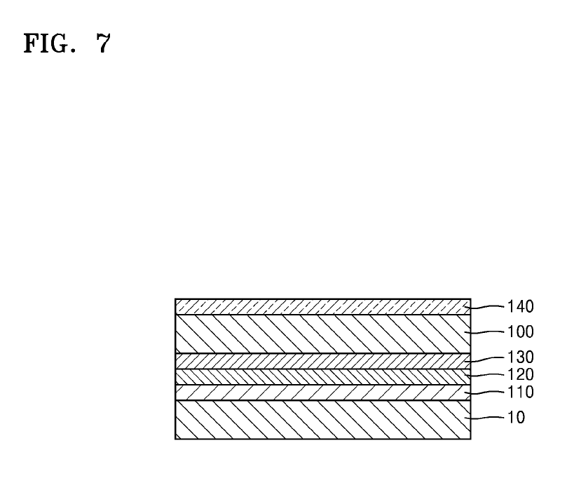

Referring to FIG. 7, the flexible substrate 100 may be formed on the first material layer 130, and then, the second barrier layer 140 may be formed on the flexible substrate 100.

The flexible substrate 100, which has flexible characteristics, may include one or more materials, such as PET, PEN, and plastic such as polyimide.

The second barrier layer 140 may include an inorganic material and for example, may include silicon oxide and/or silicon nitride, but exemplary embodiments are not limited thereto.

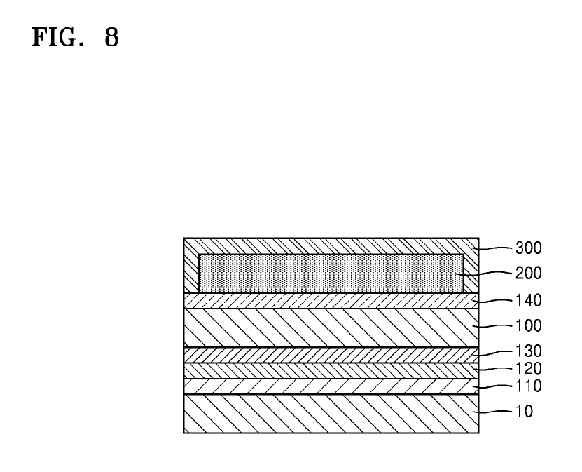

Referring to FIG. 8, the display unit 200 may be formed on the second barrier layer 140, and then, a thin film encapsulation layer covering the display unit 200 may be formed on the display unit 200. A detailed structure of the display unit 200 is the same as described above with reference to FIG. 5, and accordingly, a repeated description thereof will be omitted.

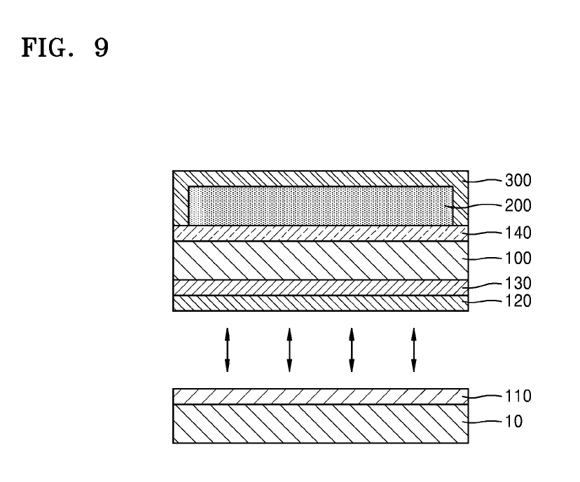

Referring to FIG. 9, the support substrate 10 and the first barrier layer 120 may be separated from each other at an interface between the sacrificial layer 110 and the first barrier layer 120. In this regard, when the first material layer 130 is not present in the process of separating the support substrate 10 and the first barrier layer 120, a detachment issue due to a difference between material properties between the first barrier layer 120 and the flexible substrate 100 arises.

That is, the first barrier layer 120 is disposed on the second surface 100b of the flexible substrate 100 in order to prevent external air permeation from the second surface 100b of the flexible substrate 100. The first barrier layer 120 may include an inorganic material, whereas the flexible substrate 100 may include an organic material such as plastic. Accordingly, although the flexible substrate 100 and the first barrier layer 120 have to be closely attached to each other in order to prevent external air permeation into the flexible substrate 100, a problem such as an issue of poor detachment or an issue of bubble formation between an organic layer and an inorganic layer may occur due to a difference in properties of the materials of the flexible substrate 100 and the first barrier layer 120.

Accordingly, in a method of manufacturing a flexible display device according to the present exemplary embodiment, as described above, the first material layer 130 may be formed between the flexible substrate 100 and the first barrier layer 120. The first material layer 130 may be directly between the flexible substrate 100 and the first barrier layer 120 and may directly contact the flexible substrate 100 and the first barrier layer 120 surface-to-surface.

One surface of the first material layer 130 contacts the flexible substrate 100 and at the same time, the other surface of the first material layer 130 contacts the first barrier layer 120, the first material layer 130 including metal or metal oxide. The first material layer 130 including metal or metal oxide has excellent adhesion characteristics with both an organic layer and an inorganic layer and accordingly, the first material layer 130 between the flexible substrate 100 and the first barrier layer 120 may significantly solve issues of poor detachment, bubble formation between an organic layer and an inorganic layer, or the like, which are due to a difference in properties of materials of the layers. Also, as the first material layer 130 may serve as a barrier as well, an effect that two or more flexible substrates 100 are provided may be produced.

As described above, at least one of the disclosed embodiments provides a flexible display device easy to manufacture and resistant to external moisture permeation and a method of manufacturing the flexible display device. However, such an effect does not pose a limitation on the scope of the inventive concept.

It should be understood that exemplary embodiments described herein should be considered in a descriptive sense only and not for purposes of limitation. Descriptions of features or aspects within each exemplary embodiment should typically be considered as available for other similar features or aspects in other exemplary embodiments.

While the inventive technology has been described with reference to the figures, it will be understood by those of ordinary skill in the art that various changes in form and details may be made therein without departing from the spirit and scope as defined by the following claims.

What is claimed is:

1. A flexible display device comprising:
a flexible substrate comprising a first surface and a second surface opposite to the first surface;
a display unit over the first surface of the flexible substrate;
a first barrier layer over the second surface of the flexible substrate; and
a first material layer between the first barrier layer and the flexible substrate, wherein the first material layer comprises metal.

2. The flexible display device of claim 1, further comprising a second barrier layer between the flexible substrate and the display unit.

3. The flexible display device of claim 2, wherein each of the first and second barrier layers comprises an inorganic material.

4. The flexible display device of claim 1, wherein the first material layer comprises metal oxide.

5. The flexible display device of claim 2, further comprising a second material layer between the flexible substrate and the second barrier layer, wherein the second material layer comprises metal.

6. The flexible display device of claim 5, wherein the second material layer comprises metal oxide.

7. The flexible display device of claim 2, wherein the flexible substrate further comprises a side surface interconnecting the first and second surfaces, and wherein the second barrier layer covers the first surface and the side surface of the flexible substrate.

8. The flexible display device of claim 7, wherein the side surface of the flexible substrate directly contacts the first material layer.

9. The flexible display device of claim 1, wherein the first material layer has the same width as that of the first barrier layer and that of the flexible substrate.

10. The flexible display device of claim 1, wherein the first material layer is thinner than the flexible substrate.

11. A flexible display device comprising:
a flexible substrate comprising a first surface and a second surface opposite to the first surface;
a display unit over the first surface of the flexible substrate;
a first barrier layer over the second surface of the flexible substrate; and
a first material layer between the flexible substrate and the display unit, wherein the first material layer comprises metal.

12. The flexible display device of claim 11, further comprising a second barrier layer between the first material layer and the display unit.

13. The flexible display device of claim 12, wherein the first material layer comprises metal oxide.

14. A method of manufacturing a flexible display device, the method comprising:
forming a sacrificial layer over a support substrate, the sacrificial layer comprising an inorganic material;
forming a first barrier layer over the sacrificial layer;
forming a first material layer over the first barrier layer, the first material layer comprising metal;
forming a flexible substrate over the first material layer; and
separating the first barrier layer from the support substrate.

15. The method of claim 14, further comprising:
forming a display unit over the flexible substrate; and
forming a second barrier layer between the flexible substrate and the display unit.

16. The method of claim 15, wherein each of the first and second barrier layers comprises an inorganic material.

17. The method of claim 15, further comprising forming a second material layer between the flexible substrate and the second barrier layer, the second material layer comprising metal.

18. The method of claim 17, wherein the second material layer further comprises oxygen binding to the metal.

19. The method of claim 14, wherein the sacrificial layer comprises an oxide comprising at least one refractory metal.

20. The method of claim 14, wherein the first material layer further comprises oxygen binding to the metal.
